(19) United States
(12) Patent Application Publication
(10) Pub. No.: US 2024/0030346 A1
(43) Pub. Date: Jan. 25, 2024

(54) RECONFIGURABLE AMBIPOLAR TRANSISTOR

(71) Applicant: UIF (University Industry Foundation), Yonsei University, Seoul (KR)

(72) Inventors: Jiwon Chang, Gangnam-gu (KR); Eunyeong YANG, Seodaemun-gu (KT)

(21) Appl. No.: 18/357,144

(22) Filed: Jul. 23, 2023

(30) Foreign Application Priority Data
Jul. 25, 2022 (KR) 10-2022-0092030

(51) Int. Cl. H01L 29/78; H01L 29/51; H01L 29/10

(52) U.S. Cl. CPC H01L 29/78391; H01L 29/516; H01L 29/1033

(57) ABSTRACT

An ambipolar transistor according to the embodiment includes: a back electrode; a first ferroelectric pattern and a second ferroelectric pattern located on the back electrode and spaced apart from each other; a first electrode located on the first ferroelectric pattern and a second electrode located on the second ferroelectric pattern; a channel part connected between the first electrode and the second electrode, and including a first channel doped with a first type and a second channel doped with a second type; and a gate stack located on the channel part.

### CROSS-REFERENCE TO RELATED APPLICATION

This application claims priority to and the benefit of Korean Patent Application No. 10-2022-0092030, filed on Jul. 25, 2022, the disclosure of which is incorporated herein by reference in its entirety.

### BACKGROUND

### 1. Field of the Invention

The present technology relates to a reconfigurable ambipolar transistor.

### 2. Discussion of Related Art

A modern electronic element is based on a metal-oxide semiconductor (MOS) transistor. The MOS transistor is an element including three electrodes of a source, a drain, and a gate which controls a channel formed between the source and the drain, and a body electrode. When a voltage corresponding to a preset threshold voltage is supplied to the gate, a channel is formed between the drain and the source, and thus the drain and the source are electrically conductive. In an N-type transistor, a channel formed of electrons is formed and thus the source and the drain are electrically connected, and in a P-type transistor, a channel formed of holes is formed. That is, any one type of MOS transistor is conductive and makes current flow with one carrier of the electron and the hole, and thus is called a unipolar transistor.

### SUMMARY OF THE INVENTION

A transistor according to the related art is formed in any one of an N-type and a P-type in a manufacturing process, and one conductivity type is selected and formed in a design process and a manufacturing process of a circuit. Accordingly, when a voltage provided to a gate of a transistor is changed to form a channel in the transistor, two types of transistors should be formed.

The present technology is provided to solve the above-described difficulties of the related art. The present technology is directed to providing a transistor capable of providing an electrical signal to control a conductivity type.

An ambipolar transistor according to the embodiment includes: a back electrode; a first ferroelectric pattern and a second ferroelectric pattern located on the back electrode and spaced apart from each other; a first electrode located on the first ferroelectric pattern and a second electrode located on the second ferroelectric pattern; a channel part connected between the first electrode and the second electrode, and including a first channel doped with a first type and a second channel doped with a second type; and a gate stack located on the channel part.

An ambipolar transistor according to the embodiment includes: a substrate; an insulating film formed on the substrate; a first electrode and a second electrode located on the insulating film; a channel part located on the insulating film and connected between the first electrode and the second electrode, and including a first channel doped with a first type and a second channel doped with a second type; and a first ferroelectric pattern and a second ferroelectric pattern located on at least the channel part; and a gate located above the first ferroelectric pattern and the second ferroelectric pattern.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a cross-sectional view illustrating an outline of an ambipolar transistor according to a first embodiment;

FIG. 2 is a perspective view illustrating a portion of the ambipolar transistor according to the first embodiment;

FIG. 3 is a view illustrating an outline of a back electrode, a first ferroelectric pattern, and a second ferroelectric pattern;

FIG. 4 is a view illustrating a projection of a first channel, a projection of a second channel, a projection of a first ferroelectric pattern, and a projection of a second ferroelectric pattern in a direction of the back electrode in the ambipolar transistor according to the first embodiment;

FIG. 5A is an exemplary cross-sectional view including the first channel in a state in which a dipole control signal V_{B} is provided and thus dipoles D are aligned, FIG. 5B is an exemplary cross-sectional view including the second channel in a state in which the dipole control signal is provided and thus the dipoles are aligned, and FIG. 5C is a view illustrating the dipole control signal;

FIG. 6A is an exemplary cross-sectional view including the first channel in a state in which a dipole control signal is provided and thus dipoles D are aligned, FIG. 6B is an exemplary cross-sectional view including the second channel in a state in which the dipole control signal is provided and thus the dipoles are aligned, and FIG. 6C is a view illustrating the dipole control signal;

FIG. 7 is a cross-sectional view schematically illustrating a cross-section of an ambipolar transistor according to a second embodiment;

FIG. 8 is a perspective view schematically illustrating a portion of the ambipolar transistor according to the second embodiment;

FIG. 9 is a view schematically illustrating a projection of a first ferroelectric pattern in a direction of the substrate, a projection of a second ferroelectric pattern in the direction of the substrate, a projection of a first channel in the direction of the substrate, and a projection of a second channel in the direction of the substrate;

FIG. 10A is an exemplary cross-sectional view including the first channel in a state in which a dipole control signal is provided and thus dipoles are aligned, FIG. 10B is an exemplary cross-sectional view including the second channel in a state in which the dipole control signal is provided and thus the dipoles are aligned, and FIG. 10C is a view illustrating the dipole control signal; and

FIG. 11A is an exemplary cross-sectional view including the first channel in a state in which a dipole control signal is provided and thus dipoles are aligned, FIG. 11B is an exemplary cross-sectional view including the second channel in a state in which the dipole control signal is provided and thus the dipoles are aligned, and FIG. 11C is a view illustrating the dipole control signal.

### DETAILED DESCRIPTION OF EXEMPLARY EMBODIMENTS

Hereinafter, embodiments of the present disclosure will be described with reference to the accompanying drawings.

### First Embodiment

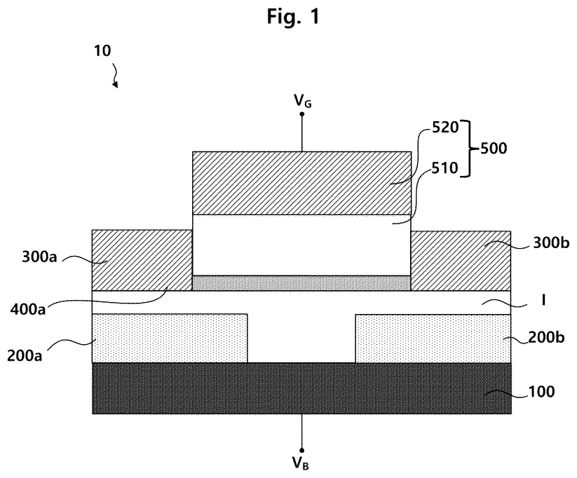

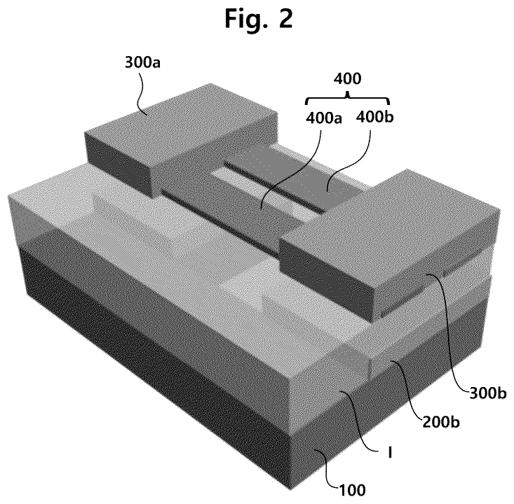

FIG. 1 is a cross-sectional view illustrating an outline of an ambipolar transistor according to a first embodiment. FIG. 2 is a perspective view illustrating a portion of the ambipolar transistor according to the first embodiment. Referring to FIGS. 1 and 2, the ambipolar transistor according to the first embodiment includes a back electrode 100, a first ferroelectric pattern 200a and a second ferroelectric pattern 200b located on the back electrode 100 and spaced apart from each other, a first electrode 300a located on the first ferroelectric pattern 200a and a second electrode 300b located on the second ferroelectric pattern 200b, a channel part 400 connected between the first electrode 300a and the second electrode 300b, and including a first channel 400a doped with a first type and a second channel 400b doped with a second type, and a gate stack 500 located on the channel part 400.

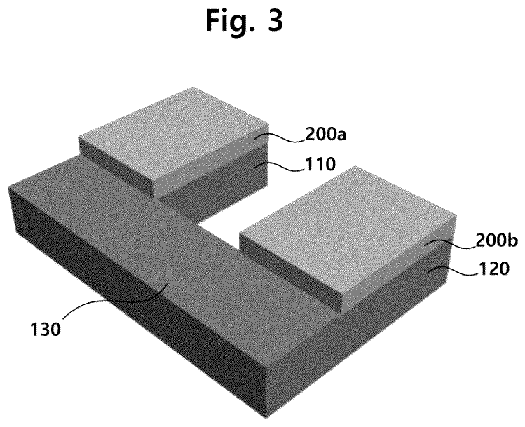

FIG. 3 is a view illustrating an outline of the back electrode 100, the first ferroelectric pattern 200a, and the second ferroelectric pattern 200b. Referring to FIGS. 1 to 3, the first ferroelectric pattern 200a and the second ferroelectric pattern 200b are located on the back electrode 100. In one embodiment, the back electrode 100 may include a first pattern part 110, a second pattern part 120, and an extending part 130, and may extend toward the first pattern part 110 from the extending part 130 and extend toward the second pattern part 120 from the extending part 130. The first pattern part 110 and the second pattern part 120 may not come into contact with each other. The back electrode 100 may have a U shape as in the illustrated embodiment.

By forming the back electrode 100 in this way, an advantage in that influence by a dipole control signal V_{B} provided through the back electrode 100 may be limited to only the first ferroelectric pattern 200a and the second ferroelectric pattern 200b, and may minimally affect the channel part 400 is provided. Furthermore, an advantage in that area consumption for forming the ambipolar transistor may be reduced by forming the back electrode 100 on the lower side is provided.

According to another embodiment not shown, the back electrode 100 may have an unpatterned plate form. By forming the back electrode 100 in this form, an advantage in that a process of patterning the back electrode 100 may be omitted, and thus the process may be simplified is provided.

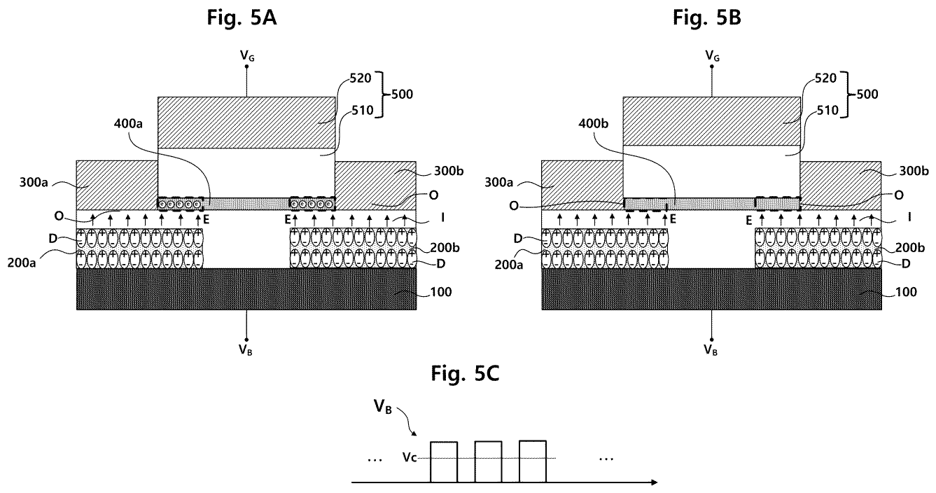

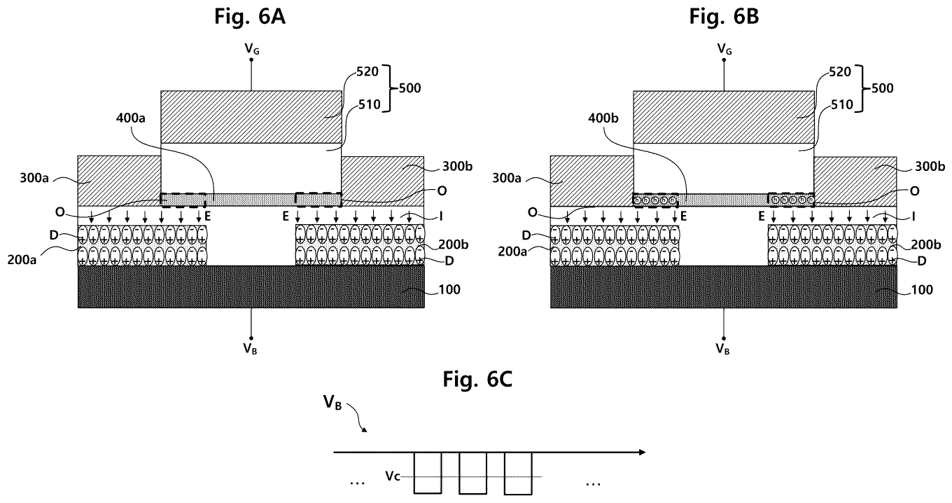

The first ferroelectric pattern 200a and the second ferroelectric pattern 200b are formed of a ferroelectric material. In one embodiment, the ferroelectric material capable of forming the first ferroelectric pattern 200a and the second ferroelectric pattern 200b is a material that achieves spontaneous polarization even when an electric field is not provided, and is a material whose direction of polarization may be switched by an electric field provided from the outside. A dipole is formed between the first ferroelectric pattern 200a and the second ferroelectric pattern 200b by spontaneous polarization, and when the dipole control signal V_{B} having an amplitude greater than or equal to a coercive voltage (V_{C}, see FIGS. 5 and 6) is provided, the direction of the dipole is reversed (switched).

Since an electric field is provided to the first ferroelectric pattern 200a and the second ferroelectric pattern 200b according to the dipole control signal V_{B} applied from the back electrode 100, the directions of dipoles are controlled.

In one embodiment, each of the ferroelectric materials included in the first ferroelectric pattern 200a and the second ferroelectric pattern 200b may include any one or more of organic materials having ferroelectric characteristics such as HZO(Zr:HfO₂), Al:HfO₂, Si:HfO₂ P(VDF-TrFE) (poly (vinylidenefluoride-co-trifluoroethylene), polyvinylidene fluoride (PVDF), polytrifluoroethylene, odd-numbered nylon, and the like and inorganic materials having ferroelectric characteristics such as PZT, BaTiO₃, PbTiO₃, and the like.

The channel part 400 is located above the first ferroelectric pattern 200a and the second ferroelectric pattern 200b. The channel part 400 includes the first channel 400a and the second channel 400b. The illustrated embodiment exemplifies a case in which the first channel 400a and the second channel 400b are separated. However, according to an embodiment not shown, the first channel 400a and the second channel 400b may be formed by doping a single semiconductor with different types.

In one embodiment, the first channel 400a may be doped with an N type, and the second channel 400b may be doped with a P type.

In an embodiment not shown, a spacer may be formed on a sidewall of the gate stack 500. The spacer may be formed of an insulating material including an oxide film, a nitride film, or the like.

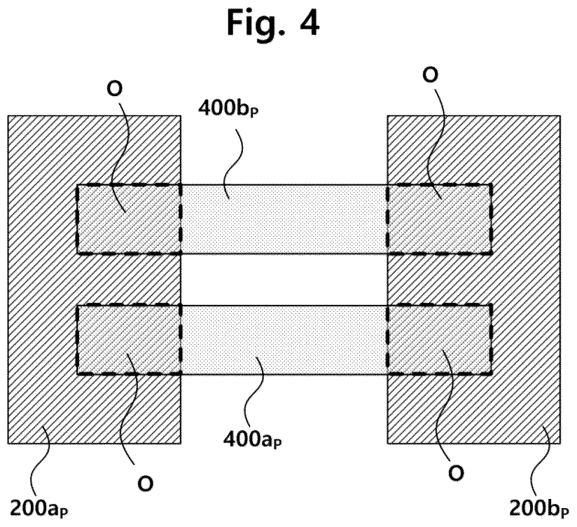

FIG. 4 is a view illustrating a projection 400a_{P} of the first channel, a projection 400b_{P} of the second channel, a projection 200a_{P} of the first ferroelectric pattern, and a projection 200b_{P} of the second ferroelectric pattern in a vertical direction toward the back electrode 100 in the ambipolar transistor according to the first embodiment. Referring to FIG. 4, as shown by thick broken lines, the projection 400a_{P} of the first channel, the projection 400b_{P} of the second channel, the projection 200a_{P} of the second ferroelectric pattern, and the projection 200b_{P} of the second ferroelectric pattern are formed with overlapping regions O overlapping each other.

As will be described below, the dipoles located in the first ferroelectric pattern 200a and the second ferroelectric pattern 200b may form an electric field to affect the first channel 400a and the second channel 400b located in the overlapping regions O.

The first electrode 300a is electrically connected to one end of each of the first channel 400a and the second channel 400b, and the second electrode 300b is electrically connected to the other end of each of the first channel 400a and the second channel 400b. In one embodiment, each of the first electrode 300a and the second electrode 300b is formed by including any one or more of a conductor and metal such as a semiconductor, gold (Au), chromium (Cr), titanium (Ti), titanium nitride (TiN), palladium (Pd), platinum (Pt), and the like. For example, when the first electrode 300a functions as a source of the transistor, the second electrode 300b may function as a drain. As another example, when the first electrode 300a functions as a drain of the transistor, the second electrode 300b may function as a source.

The ambipolar transistor of the first embodiment may further include an insulating layer I. For example, the first ferroelectric pattern 200a, the second ferroelectric pattern 200b, the first electrode 300a, and the second electrode 300b are insulated from each other by the insulating layer I. In one embodiment, the insulating layer I may be formed of a material having an electrically insulating property, and for example, may be formed of any one or more of an oxide film and a nitride film.

The gate stack 500 may include a gate 520 and a gate insulating film 510. The gate 520 may be formed by including one or more of conductors such as a semiconductor, gold (Au), chromium (Cr), titanium (Ti), titanium nitride (TiN), palladium (Pd), platinum (Pt), and the like. For example, the gate 520 may be formed of the same material as the first electrode 300a and the second electrode 300b.

The gate insulating film 510 insulates the first electrode 300a, the second electrode 300b, the first channel 400a, the second channel 400b, and the gate 520 from each other. In one embodiment, the gate insulating film 510 may be formed of any one of an oxide film and a nitride film. For example, the gate insulating film 510 may be formed of the same material as the insulating layer I.

FIGS. 5 and 6 are views for describing the operation of the first embodiment of the ambipolar transistor, wherein FIG. 5A is an exemplary cross-sectional view including the first channel 400a in a state in which the dipole control signal V_{B} is provided and thus dipoles D are aligned, FIG. 5B is an exemplary cross-sectional view including the second channel 400b in a state in which the dipole control signal V_{B} is provided and thus the dipoles D are aligned, and FIG. 5C is a view illustrating the dipole control signal V_{B}. Referring to FIGS. 5A to 5C, the dipole control signal V_{B} may be a pulse train including a plurality of pulses. The dipoles D included in the first ferroelectric pattern 200a and the second ferroelectric pattern 200b are arranged to correspond to an amplitude of each pulse included in the pulse train, the number of pulses included in the pulse train, and a duty ratio of the pulses.

The embodiment illustrated in FIGS. 5A and 5B illustrates that all of the dipoles D included in the first ferroelectric pattern 200a and the second ferroelectric pattern 200b are arranged in the same direction. However, the degree to which the dipoles D are arranged may be controlled by one or more of the amplitude of the pulse included in the dipole control signal V_{B}, the number of pulses included in the pulse train, a pulse width, and the duty ratio of the pulses.

That is, the number of dipoles arranged in the same direction may increase as magnitude of the pulse amplitude included in the dipole control signal V_{B} is larger, the number of pulses included in the pulse train is larger, the pulse width is wider, and/or the duty ratio of the pulses is larger.

Referring to FIG. 5A, when the dipoles D included in the first ferroelectric pattern 200a and the second ferroelectric pattern 200b are arranged according to the dipole control signal V_{B}, an electric field E formed by the dipoles D is provided to the overlapping regions O, and accordingly, carriers corresponding to the electric field E are accumulated in the overlapping regions O of the first channel 400a.

That is, like a case in which a positive voltage is provided to the gate 520, electrons, which are carriers, are accumulated in the overlapping regions O of the first channel 400a from the electric field formed by the dipoles D.

On the other hand, in the embodiment illustrated in FIG. 5B, in the second channel 400b doped with a conductivity type opposite that of the first channel 400a, the electric field E formed by the arranged dipoles D is provided to the overlapping regions O, but the carriers are not accumulated in the overlapping regions O.

When a positive gate voltage is applied through the gate 520, in the first channel 400a, a channel is formed between the first electrode 300a and the second electrode 300b together with the electrons accumulated by the electric field formed by the dipoles D, and the first electrode 300a and the second electrode 300b are conductive. Accordingly, since both the electric field formed by the dipoles D and the positive gate voltage provided through the gate 520 affect the conduction of the first channel 400a, conduction characteristics such as conduction resistance and the like of the first channel 400a are improved.

On the other hand, since the positive voltage provided to the gate affects the second channel 400b together with the electric field formed by the dipoles D, and thus holes, which are carriers, are not accumulated in the second channel 400b, a channel is not formed. Accordingly, the first electrode 300a and the second electrode 300b are blocked. Accordingly, since both the electric field formed by the dipoles D and the positive gate voltage provided through the gate 520 affect the blocking of the second channel 400b doped with a conductivity type opposite that of the first channel 400a, blocking characteristics such as blocking resistance, blocking current, and the like of the second channel 400b are improved.

FIG. 6A is an exemplary cross-sectional view including the first channel 400a in a state in which the dipole control signal V_{B} is provided and thus dipoles D are aligned, FIG. 6B is an exemplary cross-sectional view including the second channel 400b in a state in which the dipole control signal V_{B} is provided and thus the dipoles D are aligned, and FIG. 6C is a view illustrating the dipole control signal V_{B}. Referring to FIGS. 6A to 6C, as described above, the dipole control signal V_{B} may be a pulse train including a plurality of pulses, and the dipoles D included in the first ferroelectric pattern 200a and the second ferroelectric pattern 200b are arranged to correspond to the dipole control signal V_{B}.

In the illustrated embodiment, it is illustrated that all of the dipoles D included in the first ferroelectric pattern 200a and the second ferroelectric pattern 200b are arranged in the same direction. However, as described above, the degree to which the dipoles D are arranged may be controlled by the dipole control signal V_{B}.

In the embodiment illustrated in FIG. 6B, when the dipoles D included in the first ferroelectric pattern 200a and the second ferroelectric pattern 200b are arranged according to the dipole control signal V_{B}, an electric field E formed by the dipoles D is provided to the overlapping regions O, and accordingly, holes, which are carriers, corresponding to the electric field E are accumulated in the overlapping regions O of the second channel 400b.

On the other hand, in the first channel 400a doped with a conductivity type opposite that of the second channel 400b, the electric field E formed by the arranged dipoles D is provided to the overlapping regions O, but the carriers are not accumulated in the overlapping regions O.

As illustrated in FIG. 6A, an effect similar to a case in which a negative voltage is applied to the gate 520 from the electric field formed by the dipoles D is provided to the overlapping regions O of the first channel 400a. Accordingly, when a negative gate voltage is applied through the gate 520, the electrons, which are carriers, are not accumulated in the first channel 400a. Accordingly, a channel is not formed in the first channel 400a.

Accordingly, since the channel is not formed in the first channel 400a and thus the first channel 400a is blocked, and both the electric field formed by the dipoles D and the negative gate voltage provided through the gate 520 affect the blocking of the first channel 400a, blocking characteristics such as blocking resistance, blocking current, and the like are improved.

On the other hand, when the negative gate voltage is applied through the gate 520, in the second channel 400b, a channel is formed between the first electrode 300a and the second electrode 300b together with the electrons accumulated by the electric field formed by the dipoles D, and the first electrode 300a and the second electrode 300b are conductive. Accordingly, since both the electric field formed by the dipoles D and the negative gate voltage provided through the gate 520 affect conduction of the second channel 400b, conduction characteristics such as conduction resistance and the like of the second channel 400b are improved.

According to the above-described embodiment, it can be seen that the ambipolar transistor may be selectively reconfigured into N and P types according to the dipole control signal V_{B} applied through the back electrode. Furthermore, an advantage in that conduction characteristics such as conduction resistance and the like and blocking characteristics such as blocking resistance, leakage current, and the like are improved is provided to the reconfigured ambipolar transistor.

### Second Embodiment

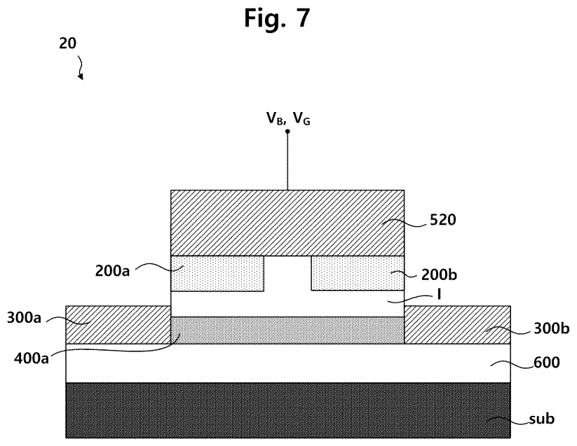

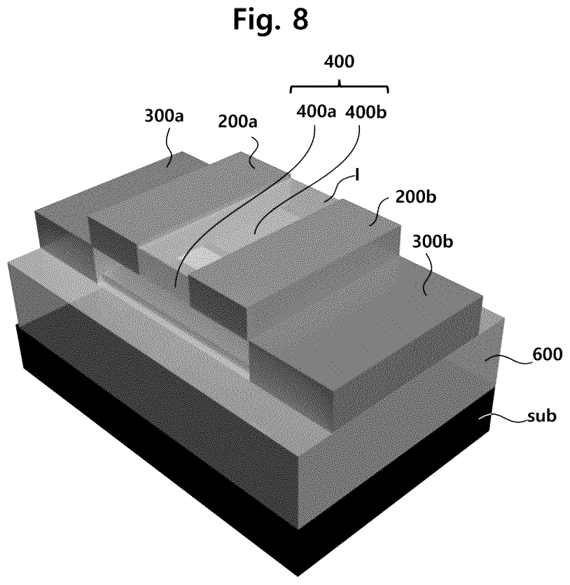

Hereinafter, an ambipolar transistor 20 according to a second embodiment will be described with reference to the accompanying drawings. However, for concise and clear description, descriptions of components the same as or similar to those of the first embodiment will be omitted. FIG. 7 is a cross-sectional view schematically illustrating a cross-section of the ambipolar transistor according to the second embodiment, and FIG. 8 is a perspective view schematically illustrating a portion of the ambipolar transistor according to the second embodiment.

Referring to FIGS. 7 and 8, the ambipolar transistor according to the second embodiment includes a substrate sub, an insulating film 600 formed on the substrate sub, a first electrode 300a and a second electrode 300b located on the insulating film 600, a channel part 400 located on the insulating film 600 and connected between the first electrode 300a and the second electrode 300b, and including a first channel 400a doped with a first type and a second channel 400b doped with a second type, a first ferroelectric pattern 200a and a second ferroelectric pattern 200b located on at least the channel part 400, and a gate 520 located above the first ferroelectric pattern 200a and the second ferroelectric pattern 200b.

In the illustrated embodiment, the substrate sub may be any one of a glass substrate and a semiconductor substrate. The insulating film 600 may be formed on the substrate sub, and the insulating film 600 may include, for example, any one of an oxide film and a nitride film.

The first channel 400a, the second channel 400b, the first electrode 300a, the second electrode 300b, and the gate 520 formed on the insulating film 600 may be insulated by an insulating layer I. In the illustrated embodiment, the insulating layer I may insulate the gate 520 and the channel part 400. The insulating layer I may function as an insulating film of the gate 520 in the transistor.

The insulating layer I may be formed by, for example, forming and planarizing an inorganic insulating film such as a nitride film, an oxide film, or the like. As another example, the insulating layer I may be formed by forming an organic insulating film by a method such as spin coating or the like.

In an embodiment not shown, a spacer may be formed on at least a sidewall of the gate 520. The spacer may be formed of an insulating material including an oxide film, a nitride film, or the like.

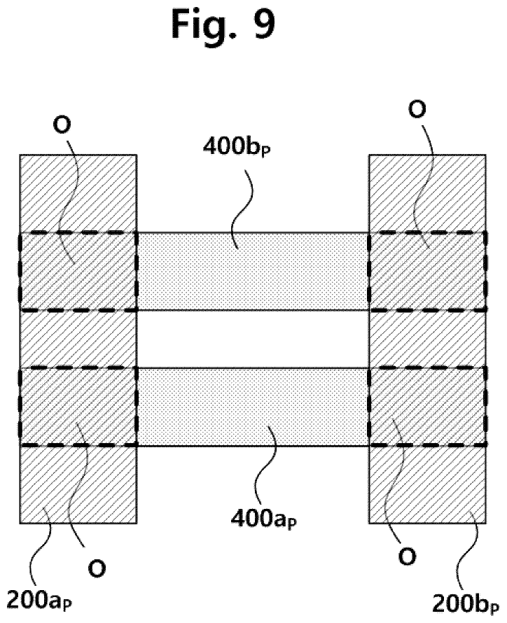

FIG. 9 is a view schematically illustrating a projection of the first ferroelectric pattern 200a in a direction of the substrate sub, a projection of the second ferroelectric pattern 200b in the direction of the substrate sub, a projection of the first channel 400a in the direction of the substrate sub, and a projection of the second channel 400b in the direction of the substrate sub. Referring to FIG. 9, a projection 400a_{P} of the first channel 400a in the direction of the substrate sub, a projection 200a_{P} of the first ferroelectric pattern 200a in the direction of the substrate sub, and a projection 200b_{P} of the second ferroelectric pattern 200b in the direction of the substrate sub overlap each other to form overlapping regions O. Likewise, the projection 200b_{P} of the second ferroelectric pattern 200b in the direction of the substrate sub, the projection 400a_{P} of the first channel 400a in the direction of the substrate sub, and a projection 400b_{P} of the second channel 400b in the direction of the substrate sub overlap each other to form overlapping regions O.

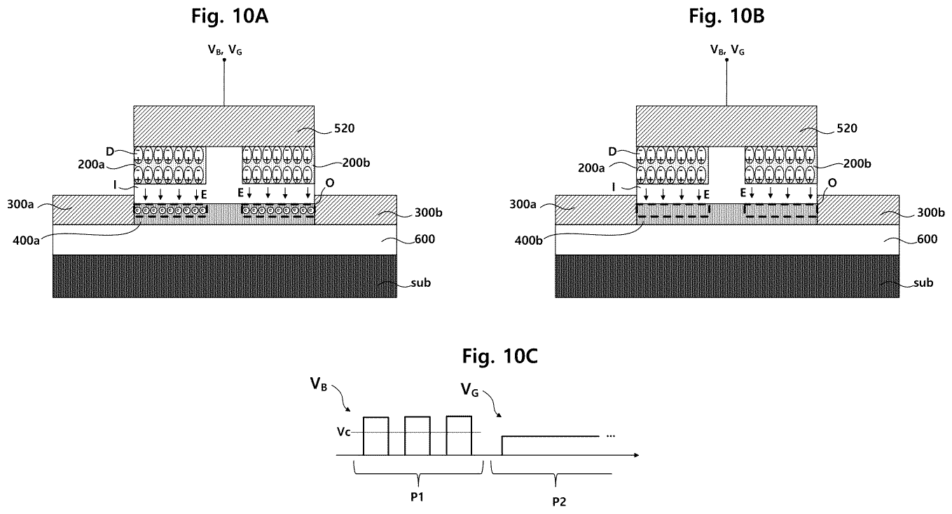

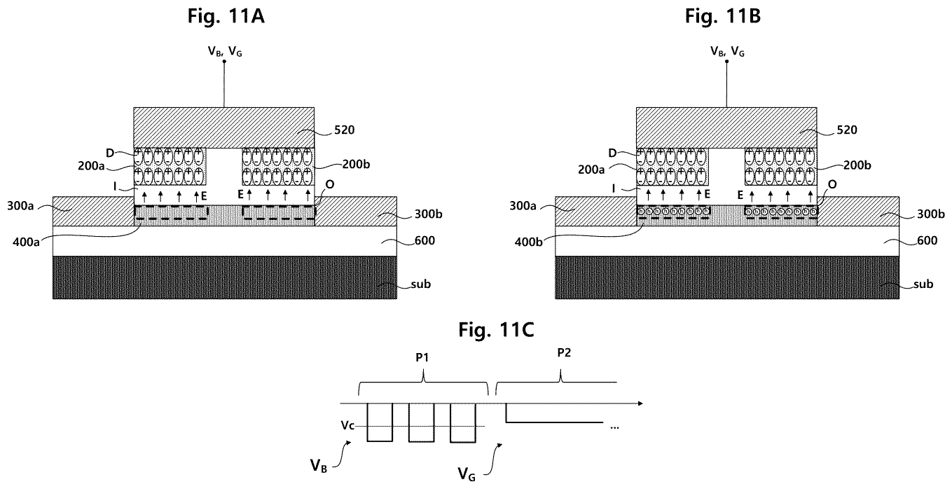

FIGS. 10 and 11 are views for describing the operation of the second embodiment of the ambipolar transistor, wherein FIG. 10A is an exemplary cross-sectional view including the first channel 400a in a state in which a dipole control signal V_{B} is provided and thus dipoles D are aligned, FIG. 10B is an exemplary cross-sectional view including the second channel 400b in a state in which the dipole control signal V_{B} is provided and thus the dipoles D are aligned, and FIG. 10C is a view illustrating the dipole control signal V_{B}.

Referring to FIGS. 10A to 10C, the dipole control signal V_{B} and a gate signal V_{G} may be provided through the gate 520 with a time difference. The dipole control signal V_{B} may be provided through the gate 520 in a first phase P1, and the gate signal V_{G} may be provided through the gate 520 in a second phase P2.

The dipole control signal V_{B} may be a pulse train including a plurality of pulses. The dipoles D included in the first ferroelectric pattern 200a and the second ferroelectric pattern 200b are arranged to correspond to an amplitude of each pulse included in the pulse train, the number of pulses included in the pulse train, and a duty ratio of the pulses.

The embodiment illustrated in FIGS. 10A and 10B illustrates that all of the dipoles D included in the first ferroelectric pattern 200a and the second ferroelectric pattern 200b are arranged in the same direction. However, the degree to which the dipoles D are arranged may be controlled by one or more of the amplitude of the pulse included in the dipole control signal V_{B}, the number of pulses included in the pulse train, a pulse width, and the duty ratio of the pulses.

That is, the number of dipoles arranged in the same direction may increase as the magnitude of the pulse amplitude included in the dipole control signal V_{B} is larger, the number of pulses included in the pulse train is larger, the pulse width is wider, and/or the duty ratio of the pulses is larger.

The ambipolar transistor 20 may be operated by applying the gate signal V_{G} after setting arrangement of the dipoles D included in the first and second ferroelectric patterns 200a and 200b by applying the dipole control signal V_{B}.

Referring to FIG. 10A, when the dipoles D included in the first ferroelectric pattern 200a and the second ferroelectric pattern 200b are arranged according to the dipole control signal V_{B}, an electric field E formed by the dipoles D is provided to the overlapping regions O, and accordingly, carriers corresponding to the electric field E are accumulated in the overlapping regions O of the first channel 400a. That is, like a case in which a positive voltage is provided to the gate 520, electrons, which are carriers, are accumulated in the overlapping regions O of the first channel 400a from the electric field formed by the dipoles D.

On the other hand, in the embodiment illustrated in FIG. 10B, in the second channel 400b doped with a conductivity type opposite that of the first channel 400a, the electric field E formed by the arranged dipoles D is provided to the overlapping regions O, but the carriers are not accumulated in the overlapping regions O.

When a positive gate voltage is applied through the gate 520, in the first channel 400a, a channel is formed between the first electrode 300a and the second electrode 300b together with the electrons accumulated by the electric field formed by the dipoles D, and the first electrode 300a and the second electrode 300b are conductive. Accordingly, since both the electric field formed by the dipoles D and the positive gate voltage provided through the gate 520 affect the conduction of the first channel 400a, conduction characteristics such as conduction resistance and the like of the first channel 400a are improved.

On the other hand, since the positive voltage provided to the gate affects the second channel 400b together with the electric field formed by the dipoles D, and thus holes, which are carriers, are not accumulated in the second channel 400b, a channel is not formed. Accordingly, the first electrode 300a and the second electrode 300b are blocked. Accordingly, since both the electric field formed by the dipoles D and the positive gate voltage provided through the gate 520 affect the blocking of the second channel 400b doped with a conductivity type opposite that of the first channel 400a, blocking characteristics such as blocking resistance, blocking current, and the like of the second channel 400b are improved.

FIG. 11A is an exemplary cross-sectional view including the first channel 400a in a state in which a dipole control signal V_{B} is provided and thus dipoles D are aligned, FIG. 11B is an exemplary cross-sectional view including the second channel 400b in a state in which the dipole control signal V_{B} is provided and thus the dipoles D are aligned, and FIG. 11C is a view illustrating the dipole control signal V_{B}. Referring to FIGS. 11A to 11C, as described above, the dipole control signal V_{B} may be a pulse train including a plurality of pulses, and the dipoles D included in the first ferroelectric pattern 200a and the second ferroelectric pattern 200b are arranged to correspond to the dipole control signal V_{B}.

In the illustrated embodiment, it is illustrated that all of the dipoles D included in the first ferroelectric pattern 200a and the second ferroelectric pattern 200b are arranged in the same direction. However, as described above, the degree to which the dipoles D are arranged may be controlled by the dipole control signal V_{B}.

In the embodiment illustrated in FIG. 11B, when the dipoles D included in the first ferroelectric pattern 200a and the second ferroelectric pattern 200b are arranged according to the dipole control signal V_{B}, the electric field E formed by the dipoles D is provided to the overlapping regions O, and accordingly, holes, which are carriers, corresponding to the electric field E are accumulated in the overlapping regions O of the second channel 400b.

On the other hand, in the first channel 400a doped with a conductivity type opposite that of the second channel 400b, the electric field E formed by the arranged dipoles D is provided to the overlapping regions O, but the carriers are not accumulated in the overlapping regions O.

As illustrated in FIG. 11A, an effect similar to a case in which a negative voltage is applied to the gate 520 from the electric field formed by the dipoles D is provided to the overlapping regions O of the first channel 400a. Accordingly, when a negative gate voltage is applied through the gate 520, the electrons, which are carriers, are not accumulated in the first channel 400a. Accordingly, a channel is not formed in the first channel 400a.

Accordingly, since the channel is not formed in the first channel 400a and thus the first channel 400a is blocked, and both the electric field formed by the dipoles D and the negative gate voltage provided through the gate 520 affect the blocking of the first channel 400a, blocking characteristics such as blocking resistance, leakage current, and the like are improved.

On the other hand, when the negative gate voltage is applied through the gate 520, in the second channel 400b, a channel is formed between the first electrode 300a and the second electrode 300b together with the electrons accumulated by the electric field formed by the dipoles D, and the first electrode 300a and the second electrode 300b are conductive. Accordingly, since both the electric field formed by the dipoles D and the negative gate voltage provided through the gate 520 affect the conduction of the second channel 400b, conduction characteristics such as conduction resistance and the like of the second channel 400b are improved.

According to the above-described embodiment, it can be seen that the ambipolar transistor may be selectively reconfigured into N and P types according to the dipole control signal V_{B} applied through the back electrode. Furthermore, an advantage in that conduction characteristics such as conduction resistance and the like and blocking characteristics such as blocking resistance, leakage current, and the like are improved is provided to the reconfigured ambipolar transistor.

The present study was conducted with support of EDA Tool from IDEC.

According to the embodiment, there is an advantage in that a reconfigurable transistor capable of controlling a conductivity type by providing an electrical signal is provided.

Although the embodiments have been described with reference to the drawings for helping understanding of the present disclosure, they are embodiments for implementation, and merely exemplary, and various modifications and equivalents may be performed by those skilled in the art. Accordingly, the true technical scope of the present disclosure should be defined by the appended claims.

What is claimed is:

1. An ambipolar transistor comprising:
a back electrode;
a first ferroelectric pattern and a second ferroelectric pattern located on the back electrode and spaced apart from each other;
a first electrode located on the first ferroelectric pattern and a second electrode located on the second ferroelectric pattern;
a channel part connected between the first electrode and the second electrode, and including a first channel doped with a first type and a second channel doped with a second type; and
a gate stack located on the channel part.

2. The ambipolar transistor of claim 1, wherein:
the back electrode includes a first pattern part, a second pattern part, and an extending part;
each of the first pattern part and the second pattern part is connected to the extending part; and
the first pattern part and the second pattern part are spaced apart from each other.

3. The ambipolar transistor of claim 2, wherein:
the first ferroelectric pattern is formed on the first pattern part; and
the second ferroelectric pattern is formed on the second pattern part.

4. The ambipolar transistor of claim 1, further comprising an insulating layer configured to insulate at least between the first ferroelectric pattern, the second ferroelectric pattern, the first electrode, the second electrode, and the channel part.

5. The ambipolar transistor of claim 1, wherein:
the first channel and the second channel are spaced apart from each other;
the first channel is a semiconductor doped with an N type; and
the second channel is a semiconductor doped with a P type.

6. The ambipolar transistor of claim 1, wherein:
the channel part is a semiconductor;
the first channel is a region where a portion of the channel part is doped with an N type;
the second channel is a region where another portion of the channel part is doped with a P type; and
the first channel and the second channel are located in the same semiconductor.

7. The ambipolar transistor of claim 1, wherein the gate stack includes at least a gate insulating film located on the channel part, and a gate electrode located on the gate insulating film

8. The ambipolar transistor of claim 7, further comprising a spacer located on a side surface of the gate stack.

9. The ambipolar transistor of claim 7, wherein:
each of the gate electrode, the first electrode, and the second electrode includes any one or more of a semiconductor, metal, gold (Au), chromium (Cr), titanium (Ti), titanium nitride (TiN), palladium (Pd), platinum (Pt), and a conductor; and
each of the first ferroelectric pattern and the second ferroelectric pattern includes any one or more of ferroelectric organic materials including any one or more of HZO(Zr:HfO₂), Al:HfO₂, Si:HfO₂ P(VDF-TrFE) (poly (vinylidenefluoride-co-trifluoroethylene), polyvinylidene fluoride (PVDF), polytrifluoroethylene, odd-numbered nylon, and ferroelectric inorganic materials including any one or more of PZT, BaTiO₃, and PbTiO₃.

10. The ambipolar transistor of claim 1, wherein:
a dipole control signal is provided to the back electrode; and
directions of dipoles formed in the first ferroelectric pattern and the second ferroelectric pattern are controlled by the dipole control signal.

11. The ambipolar transistor of claim 10, wherein:
the dipole control signal is a pulse train; and
a polarity change characteristic of the dipoles is controlled according to an amplitude, a pulse width, a duty ratio, and the number of pulses of the pulse train.

12. An ambipolar transistor comprising:
a substrate;
an insulating film formed on the substrate;
a first electrode and a second electrode located on the insulating film;
a channel part located on the insulating film and connected between the first electrode and the second electrode, and including a first channel doped with a first type and a second channel doped with a second type; and
a first ferroelectric pattern and a second ferroelectric pattern located on at least the channel part; and
a gate located above the first ferroelectric pattern and the second ferroelectric pattern.

13. The ambipolar transistor of claim 12, further comprising an insulating layer configured to insulate at least the first ferroelectric pattern and the second ferroelectric pattern, and the channel part.

14. The ambipolar transistor of claim 13, wherein the insulating layer insulates the gate and the channel part.

15. The ambipolar transistor of claim 12, wherein:
a projection of the first ferroelectric pattern in a direction of the substrate overlaps at least portions of projections of the first and second channels in the direction of the substrate; and
a projection of the second ferroelectric pattern in the direction of the substrate overlaps at least portions of the projections of the first and second channels in the direction of the substrate.

16. The ambipolar transistor of claim 12, wherein:
the first channel and the second channel are spaced apart from each other;
the first channel is a semiconductor doped with an N type; and
the second channel is a semiconductor doped with a P type.

17. The ambipolar transistor of claim 12, wherein:
the channel part is a semiconductor;
the first channel is a region where a portion of the channel part is doped with an N type;
the second channel is a region where another portion of the channel part is doped with a P type; and
the first channel and the second channel are located in the same semiconductor.

18. The ambipolar transistor of claim 12, wherein:
each of the gate electrode, the first electrode, and the second electrode includes any one or more of a semiconductor, metal, gold (Au), chromium (Cr), titanium (Ti), titanium nitride (TiN), palladium (Pd), and platinum (Pt); and
each of the first ferroelectric pattern and the second ferroelectric pattern includes any one or more of ferroelectric organic materials including any one or more of HZO(Zr:HfO₂), Al:HfO₂, Si:HfO₂ P(VDF-TrFE) (poly (vinylidenefluoride-co-trifluoroethylene), polyvinylidene fluoride (PVDF), polytrifluoroethylene, odd-numbered nylon, and ferroelectric inorganic materials including any one or more of PZT, BaTiO₃, and PbTiO₃.

19. The ambipolar transistor of claim 12, wherein:
a dipole control signal and a gate signal are provided to the gate;
the dipole control signal is a pulse train; and
the channel control signal is a direct current signal.

20. The ambipolar transistor of claim 19, wherein the dipole control signal controls directions of dipoles formed in the first ferroelectric pattern and the first ferroelectric pattern, and controls a polarity change characteristic of the dipoles using any one or more of an amplitude, a pulse width, a duty ratio, and the number of pulses of the pulse train.

21. The ambipolar transistor of claim 19, wherein an amplitude of the dipole control signal is greater than a magnitude of the channel control signal.

22. The ambipolar transistor of claim 12, wherein the substrate is any one of a glass substrate and a semiconductor substrate.

23. The ambipolar transistor of claim 12, further comprising a spacer formed on a side surface of the gate.
